(19) United States
(12) Patent Application Publication
(10) Pub. No.: US 2026/0099661 A1
(43) Pub. Date: Apr. 9, 2026

(54) MACHINE LEARNING-BASED OPTICAL PROXIMITY CORRECTION (OPC) VERIFICATION HOTSPOT CAPTURE

(71) Applicant: Siemens Industry Software Inc., Plano, TX (US)

(72) Inventors: Lianghong Yin, Fremont, CA (US); Shumay D. Shang, Saratoga, CA (US); Le Hong, Benicia, CA (US); Marko P. Chew, Palo Alto, CA (US)

(73) Assignee: Siemens Industry Software Inc., Plano, TX (US)

(21) Appl. No.: 19/348,127

(22) Filed: Oct. 2, 2025

Related U.S. Application Data
(60) Provisional application No. 63/703,346, filed on Oct. 4, 2024.

(51) Int. Cl. G06F 30/398; G03F 1/36; G06F 30/27

(52) U.S. Cl. CPC G06F 30/398; G03F 1/36; G06F 30/27

(57) ABSTRACT

Methods and systems for ML-based OPC verification hotspot capture are described herein. A method may include performing a baseline classification on layout data of a circuit design, wherein the baseline classification is based on a layout structure of edges and vertices in the layout data, wherein the baseline classification identifies different hotspot types and unique layout structures in the layout data that cause each of the different hotspot types. The method may also include training an OPC verification hotspot capture model using an output of the baseline classification as labeled training data for the OPC verification hotspot capture model and applying the trained OPC verification hotspot capture model to the layout data to detect hotspot locations in the circuit design.

### CROSS-REFERENCE TO RELATED APPLICATION

This application claims the benefit of priority to U.S. Provisional Application No. 63/703,346, filed on October 4, 2024, and titled “MACHINE LEARNING-BASED OPTICAL PROXIMITY CORRECTION (OPC) VERIFICATION HOTSPOT CAPTURE,” the entire contents of which are incorporated by reference herein.

### BACKGROUND

Electronic circuits, such as integrated circuits, are used in nearly every facet of modern society, from automobiles to microwaves to personal computers. Design of circuits may involve many steps, known as a "design flow." The particular steps of a design flow are often dependent upon the type of circuit being designed, its complexity, the design team, and the circuit fabricator or foundry that will manufacture the circuit. Electronic design automation (EDA) applications support the design and verification of circuits prior to fabrication. EDA applications may implement various EDA procedures, e.g., functions, tools, or features to analyze, test, or verify a circuit design at various stages of the design flow.

### BRIEF DESCRIPTION OF THE DRAWINGS

Certain examples are described in the following detailed description and in reference to the drawings.

FIG. 1 shows an example of a computing system that supports machine learning (ML)-based OPC verification hotspot capture.

FIG. 2 shows an example of ML-based OPC verification hotspot capture according to the present disclosure.

FIG. 3 shows an example of logic that a system may implement to support ML-based OPC verification hotspot capture.

FIG. 4 shows an example of a computing system that supports ML-based OPC verification hotspot capture.

### DETAILED DESCRIPTION

Electronic circuits, such as integrated circuits (ICs), are used in nearly every facet of modern society, from automobiles to microwaves to personal computers. The design, verification, and physical manufacture of circuit devices often involve several steps, sometimes referred to as a "design flow." The particular steps of a design flow are dependent upon various factors, such as the type of integrated circuit being designed, its complexity, the design team, and the integrated circuit fabricator (e.g., foundry) that will manufacture the physical circuit. Typically, software and hardware tools can verify the circuit designs at various stages of the design flow, for example through complex rule checks, software-based simulations, hardware-based emulation, and various other techniques supported by modern EDA technology. These steps of a design flow aid in the discovery of errors in circuit designs, and allow design teams and engineers to correct or otherwise improve the designs prior to, during, or after physical manufacture.

Optical proximity correction (OPC) verification is an effective solution to verify the correctness of full-chip OPC design and to ensure that optical and process errors have not violated design rules, optical rules, or both. For foundries and circuit manufacturers, early development stages of manufacturing processes can use OPC verifications for OPC recipe tuning and optimization experiments. During production stages, OPC verifications can be used for mask tape out, gatekeeping, and preparing hotspot monitoring points.

OPC verification has been successfully used in wafer hotspot monitoring points generation. However, such processes can require a significant amount of expertise and engineering time to develop a rule deck that effectively catches (e.g., does not miss) actual hotspots that were identified by inspection through high-precision imaging techniques such as scanning electron microscope (SEM) techniques. This may be the case as various structure patterns exist in device layouts, and the failing thresholds among different structure patterns can be very different in computational lithography. For example, long lines, line end-to-line ends, space end-to-space ends, line end-to-long lines, and convex corner-to-convex corners are each different structure patterns in circuit devices. Thus, it can be difficult to detect all kinds of hotspots that can occur in fabricated circuits using only a single constraint across an entire circuit layout. OPC verification engineers may have to develop a rule deck that involves differentiating structure types (which is also referred to as filtering), performing customized checks on each differentiated structure type, and fine-tuning the checking constraints for each structure type. This is a conventional strategy of using OPC verification to prepare, identify, or detect hotspot monitoring points for wafer inspection.

Many limitations can plague such conventional OPC verification techniques. The challenges of conventional strategies include requiring experienced engineers to write a complicated rule deck that involves all-inclusive filtering of relevant structure types as well as customized checking for each different structure type. Such conventional techniques can be time-consuming and costly, reducing the efficiency and increasing turnaround time of chip designs. Conventional techniques can also require physical wafer data to identify and set constraints for each check, which can involve high costs and long development times to fabricate test chips and extract physical wafer data.

The disclosure herein may provide systems, methods, devices, and logic for ML-based OPC verification hotspot capture. Any technical aspect described herein may be a part of the ML-based OPC verification hotspot capture technology of the present disclosure. The ML-based OPC verification hotspot capture technology of the present disclosure may use ML-based pattern classifications, e.g., to replace or in contrast to conventional custom filtering and checking techniques. Through such ML-based pattern classifications, technical benefits include simpler checks, simpler rule decks, and looser constraints for each check as compared to conventional techniques. As described herein, the ML-based OPC verification hotspot capture technology of the present disclosure can maintain the accuracy of baseline classification tools that are based on geometric edges and vertices of device layouts, while reducing a number of unique hotspot counts (e.g., unique hotspot monitoring locations), which may thus reduce the overhead of subsequent SEM inspections for hotspot detections on printed wafers. These and other technical effects and benefits of the ML-based OPC verification hotspot capture technology are presented herein.

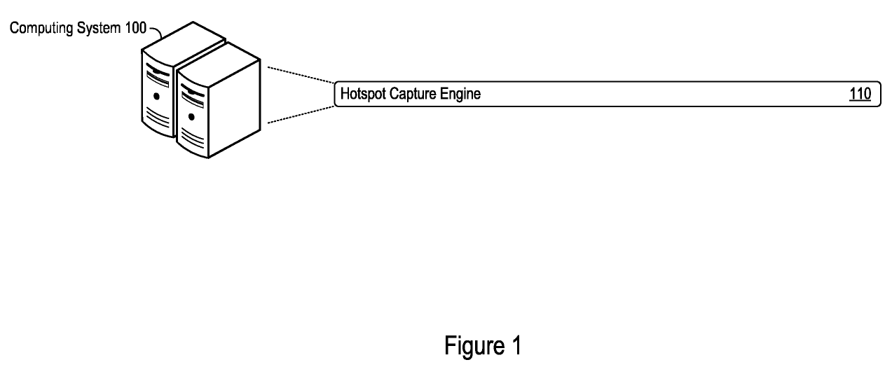

FIG. 1 shows an example of a computing system that supports ML-based OPC verification hotspot capture. The computing system 100 may take the form of a single or multiple computing devices such as application servers, compute nodes, desktop or laptop computers, smart phones or other mobile devices, tablet devices, embedded controllers, and more. In some implementations, the computing system 100 hosts, instantiates, executes, supports, or implements an EDA application or EDA system that supports circuit design and analysis, and may accordingly provide or implement any of the ML-based OPC verification hotspot capture technology described herein.

As an example implementation to support any combination of the ML-based OPC verification hotspot capture technology described herein, the computing system 100 shown in FIG. 1 includes a hotspot capture engine 110. The computing system 100 may implement the hotspot capture engine 110 (including components thereof) in various ways, for example as hardware and programming. The programming for the hotspot capture engine 110 may take the form of processor-executable instructions stored on a non-transitory machine-readable storage medium and the hardware for the hotspot capture engine 110 may include a processor to execute those instructions. A processor may take the form of single processor or multi-processor systems, and in some examples, the computing system 100 implements multiple engines using the same computing system features or hardware components (e.g., a common processor or a common storage medium).

In operation, the hotspot capture engine 110 may perform a baseline classification on layout data of a circuit design. The baseline classification may be based on a layout structure of edges and vertices in the layout data and the baseline classification may identify different hotspot types and unique layout structures in the layout data that cause each of the different hotspot types. In operation, the hotspot capture engine 110 may also train an OPC verification hotspot capture model using an output of the baseline classification as labeled training data for the OPC verification hotspot capture model as well as apply the trained OPC verification hotspot capture model to the layout data of the circuit design to detect hotspot locations in the circuit design.

These and other technical features and technical benefits of the ML-based OPC verification hotspot capture technology are described in greater detail next.

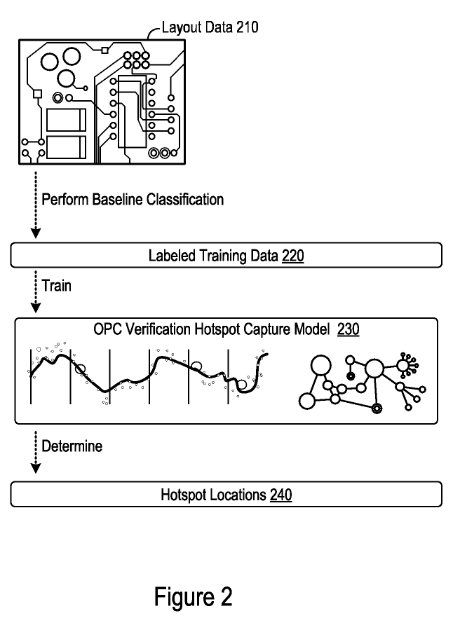

FIG. 2 shows an example of ML-based OPC verification hotspot capture according to the present disclosure. In support of ML-based OPC verification hotspot capture, the hotspot capture engine 110 may perform a baseline classification on layout data of a circuit design, such as the layout data 210 shown in FIG. 2. The layout data 210 may be a test chip or otherwise comprise layout data of a test chip. In some implementations, the layout data 210 may be a full-chip layout. In other examples, the layout data 210 may be a selected subset of a full-chip (e.g., a clip of the full-chip design). In order to identify potential hotspots (e.g., not miss any hotspots), the hotspot capture engine 110 may implement a set of primary checks that can cover some or all possible failing mechanisms. The check set may be part of an OPC verification process, e.g., a set of rules used to detect OPC failures, also referred to herein as a rule deck. OPC verifications may determine, specify, or measure edge placement errors (EPE) of fabricated contours as compared to the targets specified by the layout data 210. Various layout structures may cause an OPC error, including of a errors of a specific type. Such errors may be referred to as failing mechanisms. Failing mechanism may include, as examples, missed printing, extra printing, area, pinch, bridge, line end pull back, and space end pull out. Each failing mechanism may be analyzed, detected, or accounted for through a different primary check performed by the hotspot capture engine 110 on the layout data 210. As used herein, primary checks are also referred to simply as checks.

The hotspot capture engine 110 may set break points in the layout data 210. In some implementations, the hotspot capture engine 110 may ensure full coverage of regions in the layout data 210. For example, the hotspot capture engine 110 may implement break points set at transitions between 2-dimensional (2D) and 1-dimensional (1D) regions in the layout data 210, e.g., to maintain 2D and 1D hotspots as individual standalone data points. As another example implementation, the hotspot capture engine 110 may implement break points in 1D long lines in the layout data 210. The hotspot capture engine 110 can set the spacing of such break points based on or at a controlled sampling rate. By doing so along 1D long lines, changes in neighboring environments from one point to the next point can be accounted for. Such detected hotspots points can be likewise kept as individual standalone data points by the hotspot capture engine 110.

In some implementations, the hotspot capture engine 110 may use loose constraints on the checks. This may be the case as hotspot capture need not be constrained by threshold constraints, and instead by ranking in each structure type. Pattern classification is applied to each of the checks by the hotspot capture engine 110 as described herein. Such pattern classification may accomplish the function of custom filtering and checking of conventional techniques, but do so in a more efficient manner as compared to such conventional techniques while nonetheless maintaining accuracy. In some implementations, use of limiting functions in each hotspot type (which can be differentiated based failing mechanism) can be performed by the hotspot capture engine 110 to control output data volume. For example, limiting functions that control the number of worst duplicate hotspots in each unique class can support the setting of custom constraints. Another example of a limiting function that the hotspot capture engine 110 may employ is to limit the number of worst unique classes. The hotspot capture engine 110 may use this limiting function with caution so as to not miss (e.g., fail to identify) any unique class of hotspot. In some implementations, the hotspot capture engine 110 may split bridge checks into two scenarios (e.g., two different hotspot types), an edge-to-edge bridge hotspot type and a corner-to-corner bridge hotspot type. Each such scenario may be treated as separate hotspot type and thus have its own separate check(s) performed by the hotspot capture engine 110.

To perform checks on the layout data 210, the hotspot capture engine 110 may run lithography simulations on the layout data 210 (e.g., clips thereof) to generate simulated output contours of fabrication of the layout data 210. The hotspot capture engine 110 may then perform the checks on the simulated output in order to identify hotspots in the layout data 210. Any suitable simulation parameters, break point sampling parameters, pattern classification halo radius parameters, coarse match tolerance parameters, constraints, or other parameters for performing the checks are contemplated herein.

As noted herein, the hotspot capture engine 110 may perform a baseline classification on the layout data 210, including through analyzing the layout data 210 through an OPC verification rule deck comprised of checks for failing mechanisms described herein. The checks performed in a baseline classification may be based on geometrical edges and vertices, e.g., identified or analyzed in the layout data 210. OPC verifications through rule decks for the baseline classification may be based on exact matching for geometrical edge and vertex structures, with some coarse match tolerance allowed. The hotspot capture engine 110 may set up the rule deck and run the OPC verification (e.g., based on the rule deck) on the layout data 210. The layout data 210 may be full layout of a circuit design. Through performance of an OPC verification via the rule deck, the hotspot capture engine 110 may determine hotspot counts in the layout data, including for different failing mechanisms such as missed printing, extra printing, area, pinch, bridge, line end pull back, space end pull out, or any other suitable failing mechanism. The hotspots determined for different failing mechanisms may be referred to or otherwise understood as hotspots of different types, with checks for each failing mechanism identifying hotspots of each type. In the baseline classification, the hotspot capture engine 110 may also determine a total count of hotspots for each hotspot type as well as a unique count of hotspots for each hotspot type. As used herein, unique hotspots may also be understood as or referred to as unique layout structures in layout data, e.g., that cause a given hotspot type. Duplicates of a unique layout structure may refer to multiple occurrences of the unique layout structure in the layout data 210, e.g., within a coarse matching tolerance.

Review of the unique hotspots determined through the OPC verification can be performed. As the number of unique hotspots determined through the OPC verification can be in the millions or more (even for a single hotspot type for a given failing mechanism), hotspot review of such a large number of locations may be practically infeasible. As such, the hotspot capture engine 110 may sort the unique hotspots for a given hotspot type according to any suitable criterion. For example, the hotspot capture engine 110 may sort the unique hotspots of a given hotspot type based on a number of duplicate hotspots identified in the layout data 210. The unique hotspots with a greater number of duplicate hotspots (e.g., a greater number of occurrences within the layout data 210) may be prioritized for review. As another example, the hotspot capture engine 110 may sort by worst hotspots based on numerical property, e.g., the unique hotspots with the greatest EPE. In this example, these hotspots with highest EPE or greatest degree of error may be prioritized for review.

The hotspot capture engine 110 may support review of a selected number of unique hotspots for each hotspot type for each given failing mechanism. For example, review can be performed for 1,000 unique hotspots for each hotspot type (each with its own primary checks for the corresponding failing mechanism). The top 1,000 unique hotspots for each hotspot type can be reviewed for the sorting techniques described herein. The unique hotspots may even include OPC failures, which may be referred to as OPC failures as well. For each of the OPC failures, the hotspot capture engine 110 can support review of the target layer polygons, OPC layer polygons, lithography simulation contours, and the error marker shape. Analysis of root causes can be performed, repairs implemented, and then OPC verification can be re-run through the hotspot capture engine 110. Example repairs can include performing mask rule checking (MRC) on layout designs, fixing design defects, performing re-targeting on hard-failure target layers, and re-doing OPC mask synthesis. These review and fixes may be based on a given unique hotspot. However, the fixes can be effective on all duplicates of the given unique hotspot in the layout data 210. After the applied fixes, the hotspot capture engine 110 may ensure no hard failures remain after re-running OPC verification. The output of the OPC verification after repair (including counts for total number of hotspots and number unique hotspots for each hotspot type) may be used as an output for the baseline classification.

The hotspot capture engine 110 may support enhancements in hotspot capture for rule-based baseline classifications. As OPC verifications and rule decks may support baseline classifications based on geometrical edges and vertices, baseline classifications may be accurate, yet strict. As such, the number of unique hotspots determined through baseline classifications may be high, and too many unique hotspots (even for a given hotspot type) may be impractical to perform hotspot monitoring on a wafer through SEM or other high-precision SEM inspections. Accordingly, the ML-based OPC verification hotspot capture technology of the present disclosure may provide machine-learning capabilities to support processing of layout data based on the output of baseline classifications.

ML-based classifications of hotspots can have the potential to maintain classification accuracy while improving coarse match tolerance. Through such capabilities, ML-based classifications can reduce unique hotspot counts, which may in turn support a feasible number of SEM inspections in printed wafers. The hotspot capture engine 110 may support configuration of any ML-relevant features and feature vector kernels to support ML capabilities for hotspot classifications. For example, the hotspot capture engine 110 may focus on supporting ML-based classification of geometrically similar patterns. As such, geometrical pattern density kernels may be utilized by the hotspot capture engine 110. Example geometrical pattern density kernels the hotspot capture engine 110 may utilize include gaussian, tophat, square, rectangle, and their variant kernel designs. Halo size parameters for kernels can be specified by the hotspot capture engine 110 based on critical dimension, e.g., a 200 nanometer (nm) halo size for a 20nm critical dimension. In some implementations, the hotspot capture engine 110 may account for extreme ultraviolet (EUV) lithography exposure shadowing effect along a scanning direction for kernel designs (e.g., a scanning Y direction) used for extraction of feature vectors from locations in the layout data.

The hotspot capture engine 110 may prepare training data for a ML model to support the ML-based classification of hotspots described herein. In the example of FIG. 2, the hotspot capture engine 110 may use results from the baseline classification as the labeled part of a training dataset. The feature vectors for each hotspot location may also be included by the hotspot capture engine 110 as part of the training dataset, e.g., captured according to feature vector kernels as described herein. Thus, the labeled training data 220 may further include feature vectors extracted from the unique hotspots (e.g., the unique layout structures) in the layout data 210 determined through the baseline classification.

In the example of FIG. 2, the hotspot capture engine 110 generates the labeled training data 220. Through labeling of the specific hotspot type that corresponds to each feature vector (and hotspot location), the ML-based OPC verification hotspot capture technology of the present disclosure can ensure, improve, or maintain accuracy of ML-based classification of geometrically similar shapes in layout data of circuit designs.

In FIG. 2, the hotspot capture engine 110 trains the OPC verification hotspot capture model 230. The OPC verification hotspot capture model 230 may take the form of any suitable ML model, and the hotspot capture engine 110 may train the OPC verification hotspot capture model 230 using the labeled training data 220 using any suitable semi-supervised ML model training flow. Through the trained OPC verification hotspot capture model 230, the hotspot capture engine 110 may determine hotspot locations 240, e.g., for a full-chip layout of a circuit design. The hotspot locations may be unique hotspots (e.g., unique layout structures) determined by the OPC verification hotspot capture model 230. Put another way, the hotspot locations 240 detected by applying the trained OPC verification hotspot capture model 230 may correspond to unique layout structures in the layout data 210 determined by the trained OPC verification hotspot capture model 230.

To explain further, the hotspot capture engine 110 may apply the trained OPC verification hotspot capture model 230 to the layout data 210, and doing so can improve coarse match tolerance as compared to the baseline classification. Thus, geometrically similar layout structures in the layout data 210 that were identified as distinct layout structures in a baseline classification (and thus counted as separate unique hotspots) can instead be treated as the same unique hotspot via the ML-based classification of the OPC verification hotspot capture model 230. As such, a number of unique layout structures determined by the trained OPC verification hotspot capture model 230 for the layout data 210 may be less than a number of unique layout structures determined by the baseline classification for the layout data 210. Experimental results indicate that significant improvements can be achieved in pattern reduction ratios between a total hotspot count and a unique hotspot count for a given hotspot type. Reduction in unique hotspot counts can be achieved by the OPC verification hotspot capture model 230, e.g., as compared to baseline classifications. Experimental results show that reductions of unique hotspot counts from millions to thousands can be achieved for some hotspot types (reduced from baseline classification outputs), which can then provide an increasingly feasible number of hotspot locations for SEM inspection on a printed wafers. Some or all of the unique hotspots determined by the OPC verification hotspot capture model 230 may be selected as the hotspot locations 240 for further SEM inspection.

The ML-based OPC verification hotspot capture technology presented herein may thus provide an effective strategy that uses OPC verifications to capture hotspots (e.g., determine hotspot locations) for wafer verification, e.g., SEM inspections. In contrast to conventional customer filtering and checking techniques, the ML-based OPC verification hotspot capture technology may utilize pattern classifications to determine hotspot locations, including through classification limiting functions to replace custom constraint settings. Experimental results indicate that baseline classifications alone may be accurate, but increasingly strict and resulting in a number of unique hotspot counts that are infeasible for SEM inspection. ML-based classifications can maintain the classification accuracy of baseline classifications, (e.g., as inherited from baseline classify), while also reducing unique hotspot counts at the same time. In support of ML-based classifications, the ML-based OPC verification hotspot capture technology can include capabilities to design density kernels for feature vector capture, prepare labeled data for ML model training from baseline classify results, and more. Experimental results show that application of trained ML classify models (such as the OPC verification hotspot capture model 230) on a full-chip layout can improve pattern reduction ratio by two orders of magnitude and reduce unique hotspot count from a millions-level to a thousands-level. While many of the features were presented herein with relation, to OPC verification, the technology presented herein is not so limited, and can be consistently applied to any verification flow.

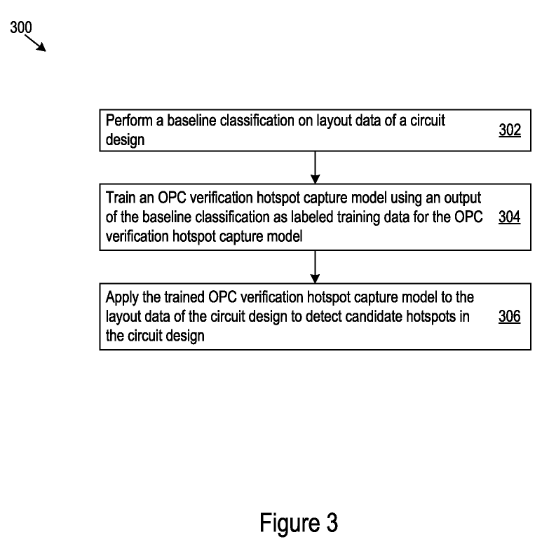

FIG. 3 shows an example of logic 300 that a system may implement to support ML-based OPC verification hotspot capture. For example, the computing system 100 may implement the logic 300 as hardware, executable instructions stored on a machine-readable medium, or as a combination of both. The computing system 100 may implement the logic 300 via the hotspot capture engine 110, through which the computing system 100 may perform or execute the logic 300 as a method to support ML-based OPC verifications for hotspot capture. The following description of the logic 300 is provided using the hotspot capture engine 110 as an example implementation. However, other implementation options by computing systems are possible.

In implementing the logic 300, the hotspot capture engine 110 may perform a baseline classification on layout data of a circuit design (302), wherein the baseline classification is based on a layout structure of edges and vertices in the layout data, wherein the baseline classification identifies different hotspot types and unique layout structures in the layout data that cause each of the different hotspot types, train an OPC verification hotspot capture model using an output of the baseline classification as labeled training data for the OPC verification hotspot capture model (304), and apply the trained OPC verification hotspot capture model to the layout data of the circuit design to detect candidate hotspots in the circuit design (306).

The logic 300 shown in FIG. 3 provides an illustrative example by which a computing system 100 may support or implement various features of the ML-based OPC verification hotspot capture technology described herein. Additional or alternative steps in the logic 300 are contemplated herein, including according to any of the various features described herein for the hotspot capture engine 110.

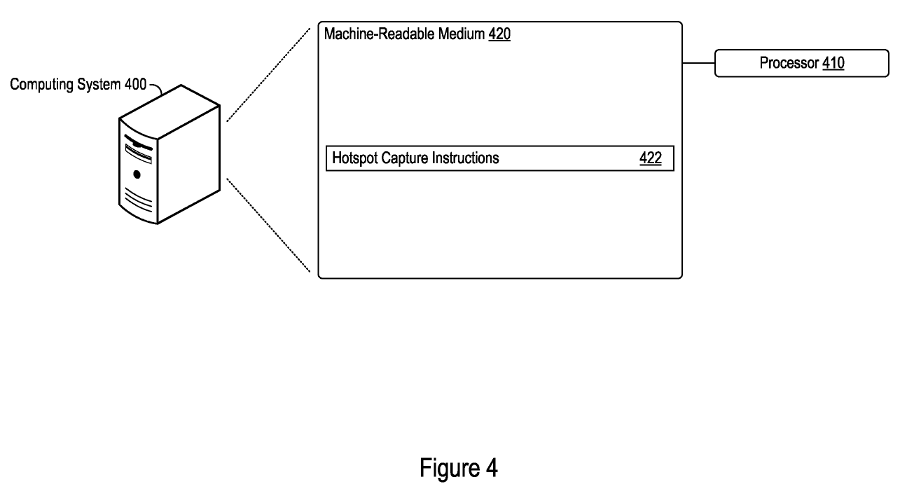

FIG. 4 shows an example of a computing system 400 that supports ML-based OPC verification hotspot capture. The computing system 400 may include a processor 410, which may take the form of a single or multiple processors. The processor(s) 410 may include a central processing unit (CPU), microprocessor, or any hardware device suitable for executing instructions stored on a machine-readable medium. The computing system 400 may include a machine-readable medium 420. The machine-readable medium 420 may take the form of any non-transitory electronic, magnetic, optical, or other physical storage device that stores executable instructions, such as the hotspot capture instructions 422 shown in FIG. 4. As such, the machine-readable medium 420 may be, for example, Random Access Memory (RAM) such as a dynamic RAM (DRAM), flash memory, spin-transfer torque memory, an Electrically-Erasable Programmable Read-Only Memory (EEPROM), a storage drive, an optical disk, and the like.

The computing system 400 may execute instructions stored on the machine-readable medium 420 through the processor 410. Executing the instructions (e.g., the hotspot capture instructions 422) may cause the computing system 400 to perform or implement any of the ML-based OPC verification hotspot capture technology described herein, including according to any aspect of the hotspot capture engine 110. For example, execution of the hotspot capture instructions 422 by the processor 410 may cause the computing system 400 to perform a baseline classification on layout data of a circuit design. The baseline classification may be based on a layout structure of edges and vertices in the layout data and the baseline classification may identify different hotspot types and unique layout structures in the layout data that cause each of the different hotspot types. Execution of the hotspot capture instructions 422 by the processor 410 may also cause the computing system 400 to train an OPC verification hotspot capture model using an output of the baseline classification as labeled training data for the OPC verification hotspot capture model as well as apply the trained OPC verification hotspot capture model to the layout data of the circuit design to detect candidate hotspots in the circuit design.

Any combination of the ML-based OPC verification hotspot capture technology as described herein may be implemented via the Hotspot capture instructions 422.

Any suitable training techniques for training of the ML models may be applied and used, including the supervised or semi-supervised ML techniques. Application of trained ML models are contemplated herein, including for hotspot detections for various other circuit designs (e.g., full-chip layout). Detected candidate hotspots may be further verified through SEM inspection, addressed through layout changes, or otherwise processed. Manufacture of circuits, with designs altered or addressed through application of the ML-based OPC verification hotspot capture technology is also contemplated herein.

The systems, methods, devices, and logic described above, including the hotspot capture engine 110, may be implemented in many different ways in many different combinations of hardware, logic, circuitry, and executable instructions stored on a machine-readable medium. For example, the hotspot capture engine 110, may include circuitry in a controller, a microprocessor, or an application specific integrated circuit (ASIC), or may be implemented with discrete logic or components, or a combination of other types of analog or digital circuitry, combined on a single integrated circuit or distributed among multiple integrated circuits. A product, such as a computer program product, may include a storage medium and machine-readable instructions stored on the medium, which when executed in an endpoint, computer system, or other device, cause the device to perform operations according to any of the description above, including according to any features of the hotspot capture engine 110.

The processing capability of the systems, devices, and engines described herein, including the hotspot capture engine 110, may be distributed among multiple system components, such as among multiple processors and memories, optionally including multiple distributed processing systems or cloud/network elements. Parameters, databases, and other data structures may be separately stored and managed, may be incorporated into a single memory or database, may be logically and physically organized in many different ways, and may be implemented in many ways, including data structures such as linked lists, hash tables, or implicit storage mechanisms. Programs may be parts (e.g., subroutines) of a single program, separate programs, distributed across several memories and processors, or implemented in many different ways, such as in a library (e.g., a shared library).

While various examples and features have been described above, many more implementations are possible.

1. A method comprising:
by a computing system:
performing a baseline classification on layout data of a circuit design, wherein the baseline classification is based on a layout structure of edges and vertices in the layout data, wherein the baseline classification identifies different hotspot types and unique layout structures in the layout data that cause each of the different hotspot types;
training an OPC verification hotspot capture model using an output of the baseline classification as labeled training data for the OPC verification hotspot capture model; and
applying the trained OPC verification hotspot capture model to the layout data to detect hotspot locations in the circuit design.

2. The method of claim 1, wherein performing the baseline classification comprises performing a different check for each of the different hotspot types.

3. The method of claim 1, wherein the hotspot locations detected by applying the trained OPC verification hotspot capture model correspond to unique layout structures in the layout data determined by the trained OPC verification hotspot capture model.

4. The method of claim 3, wherein a number of unique layout structures determined by the trained OPC verification hotspot capture model for the layout data is less than a number of unique layout structures determined by the baseline classification for the layout data.

5. The method of claim 1, wherein the labeled training data further comprises feature vectors extracted from the unique layout structures in the layout data determined through the baseline classification.

6. The method of claim 1, wherein performing the baseline classification comprises implementing break points in 1-dimensional long lines in the layout data, including by setting a space of the break points based on a controlled sampling rate.

7. The method of claim 1, wherein performing the baseline classification splitting bridge hotspot types into two different hotspot types, including an edge-to-edge bridge hotspot type and a corner-to-corner bridge hotspot type.

8. A system comprising:
a processor; and
a non-transitory machine-readable medium comprising instructions that, when executed by the processor, cause a computing system to:
perform a baseline classification on layout data of a circuit design, wherein the baseline classification is based on a layout structure of edges and vertices in the layout data, wherein the baseline classification identifies different hotspot types and unique layout structures in the layout data that cause each of the different hotspot types;
train an OPC verification hotspot capture model using an output of the baseline classification as labeled training data for the OPC verification hotspot capture model; and
apply the trained OPC verification hotspot capture model to the layout data to detect hotspot locations in the circuit design.

9. The system of claim 8, wherein the instructions, when executed, cause the computing system to perform the baseline classification by performing a different check for each of the different hotspot types.

10. The system of claim 8, wherein the hotspot locations detected by applying the trained OPC verification hotspot capture model correspond to unique layout structures in the layout data determined by the trained OPC verification hotspot capture model.

11. The system of claim 10, wherein a number of unique layout structures determined by the trained OPC verification hotspot capture model for the layout data is less than a number of unique layout structures determined by the baseline classification for the layout data.

12. The system of claim 8, wherein the labeled training data further comprises feature vectors extracted from the unique layout structures in the layout data determined through the baseline classification.

13. The system of claim 8, wherein performing the baseline classification comprises implementing break points in 1-dimensional long lines in the layout data, including by setting a space of the break points based on a controlled sampling rate.

14. The system of claim 8, wherein the instructions, when executed, cause the computing system to perform the baseline classification by splitting bridge hotspot types into two different hotspot types, including an edge-to-edge bridge hotspot type and a corner-to-corner bridge hotspot type.

15. A non-transitory machine-readable medium comprising instructions that, when executed by the processor, cause a computing system to:
perform a baseline classification on layout data of a circuit design, wherein the baseline classification is based on a layout structure of edges and vertices in the layout data, wherein the baseline classification identifies different hotspot types and unique layout structures in the layout data that cause each of the different hotspot types;
train an OPC verification hotspot capture model using an output of the baseline classification as labeled training data for the OPC verification hotspot capture model; and
apply the trained OPC verification hotspot capture model to the layout data to detect hotspot locations in the circuit design.

16. The non-transitory machine-readable medium of claim 15, wherein the instructions, when executed, cause the computing system to perform the baseline classification by performing a different check for each of the different hotspot types.

17. The non-transitory machine-readable medium of claim 15, wherein the hotspot locations detected by applying the trained OPC verification hotspot capture model correspond to unique layout structures in the layout data determined by the trained OPC verification hotspot capture model.

18. The non-transitory machine-readable medium of claim 17, wherein a number of unique layout structures determined by the trained OPC verification hotspot capture model for the layout data is less than a number of unique layout structures determined by the baseline classification for the layout data.

19. The non-transitory machine-readable medium of claim 15, wherein the labeled training data further comprises feature vectors extracted from the unique layout structures in the layout data determined through the baseline classification.

20. The non-transitory machine-readable medium of claim 15, wherein performing the baseline classification comprises implementing break points in 1-dimesional long lines in the layout data 210, including by setting a space of the break points based on a controlled sampling rate.
